(19) United States
(12) Patent Application Publication
(10) Pub. No.: US 2017/0338441 A1
(43) Pub. Date: Nov. 23, 2017

(54) DISPLAY DEVICE AND MANUFACTURING METHOD THEREOF

(71) Applicant: Japan Display Inc., Tokyo (JP)

(72) Inventor: Toshiyuki HIGANO, Tokyo (JP)

(21) Appl. No.: 15/478,347

(22) Filed: Apr. 4, 2017

(30) Foreign Application Priority Data
May 23, 2016 (JP) 2016-102474

(51) Int. Cl. H01L 51/52; H01L 27/12; H01L 27/32

(52) U.S. Cl. CPC H01L 51/5253; H01L 51/5281; H01L 27/3276; H01L 27/124; H01L 51/5262; H01L 2227/323; H01L 2251/5338

(57) ABSTRACT

In manufacturing display devices having a flexible substrate, the invention allows reduction of material cost and the number of manufacturing steps, thereby reducing manufacturing cost. A display device includes: a bendable substrate 100 having thereon a display area DA and a terminal section TA; an array layer 50 formed in the displayer area DA; and an inter-layer 160 of a predetermined width formed between the array layer 50 and the terminal section TA. The inter-layer 160 does not overlap the array layer 50 and the terminal section TA.

### CLAIM OF PRIORITY

The present application claims priority from Japanese Patent Application No. 2016-102474 filed on May 23, 2016, the content of which is hereby incorporated by reference into this application.

### BACKGROUND OF THE INVENTION

### 1. Field of the Invention

The present invention relates to display devices and particularly to a flexible display device with a bendable substrate.

### 2. Description of the Related Art

Organic electroluminescent display (OELD) devices and liquid crystal display (LCD) devices can be made thin enough to be bent flexibly for use. In such a case, the substrate on which various elements are to be formed is made of thin glass or thin resin. In terms of reducing display thickness, OELD devices have an advantage over LCD devices because the former does not involve the use of a backlight. The same is true of reflective LCD devices.

To produce a flexible display device, its substrate needs to be thin. However, reducing the thickness of the substrate makes it difficult to put the substrate through various manufacturing processes. Therefore, a relatively thick carrier substrate such as glass is used during the manufacturing processes, and it is replaced by a thinner and more flexible substrate after the completion of a mother substrate.

In JP-A-2013-145808, a heat exchanger layer such as a metal layer is disposed between a glass substrate and a transparent resin substrate. The heat exchanging layer is heated by a flash-lamp, whereby the glass substrate and the transparent resin substrate are separated from each other.

In JP-A-2014-86451, a separation layer such a metal layer is disposed between a support, that is, a carrier substrate, and a flexible substrate. The support and the flexible substrate are separated from each other by heating the separation layer through electromagnetic induction.

In JP-A-2015-174379, a laminate of a metal oxide and a polyimide-based resin which serves as a flexible substrate is formed on a glass substrate. The flexible substrate and the glass substrate are detached from each other by irradiating the metal oxide with infrared rays to heat it.

In JP-A-2015-197973, a thermally conductive resin formed of a resin and filler is applied to a support, and a device layer is formed on the thermally conductive resin. The support and the terminally conductive resin are later separated from each other.

### SUMMARY OF THE INVENTION

In all of the techniques disclosed in the above patent documents, a carrier substrate is used during manufacturing processes, and it is removed and replaced by another substrate that is part of the finished product after the completion of a mother substrate. The carrier substrate can be removed from the mother substrate before or after the mother substrate is separated into individual display cells.

In such a production method, the carrier substrate is discarded after use. Thus, the material cost associated with the carrier substrate constitutes a waste. Moreover, the use of the carrier substrate requires the steps of removing it and gluing another substrate (part of the finished product), which increases manufacturing cost.

Thus, an object of the invention is to make it possible to use a substrate that is part of the finished product during manufacturing processes without using the carrier substrate and thereby reduce the manufacturing cost of the flexible display device.

### Means for Solving the Problems

The present invention is designed to achieve the above object and can be implemented as the following device or method.

(1) A display device includes a bendable substrate having thereon a display area and a terminal section; an array layer formed in the displayer area; and an inter-layer of a predetermined width formed between the array layer and the terminal section. In the display device, the inter-layer does not overlap the array layer and the terminal section.

(2) The display device of (1) in which an optical sheet is glued in the display area and the optical sheet overlaps the inter-layer.

(3) A method of manufacturing a flexible display device includes: forming a flexible substrate on a support substrate; forming a display area and a terminal section on the flexible substrate; forming an array layer in the display area; forming an inter-layer in the terminal section; gluing an optical sheet so as to cover the array layer and the inter-layer; cutting the optical sheet at the boundary between the display area and the terminal section; and performing laser abrasion on the inter-layer formed in the terminal section to remove the part of the optical sheet that covers the terminal section.

### BRIEF DESCRIPTION OF THE DRAWINGS

FIG. 1 is a plan view of a flexible display device.

FIG. 2 is a cross section taken along line A-A of FIG. 1.

FIG. 3 is a cross section of the display area of an OELD device.

FIG. 4 is a plan view of a mother substrate.

FIG. 5 is a cross section taken along line B-B of FIG. 4.

FIG. 6 is a cross section of an OEL cell separated from the mother substrate.

FIG. 7 is a cross section illustrating the removal of a second carrier substrate from the OEL cell.

FIG. 8 is a cross section illustrating a polarizer glued to the OEL cell in place of the second carrier substrate.

FIG. 9 is a cross section illustrating the removal of a first carrier substrate from a flexible substrate.

FIG. 10 is a cross section illustrating a support substrate glued to the flexible substrate in place of the first carrier substrate.

FIG. 11 is a plan view of a mother substrate in which a mother support substrate and a mother polarizer are used in place of the first carrier substrate and the second carrier substrate, respectively.

FIG. 12 is a cross section taken along line C-C of FIG. 11.

FIG. 13 is a cross section of an OEL cell separated from the mother substrate of FIG. 12.

FIG. 14 is a plan view of a mother substrate according to the invention.

FIG. 15 is a cross section taken along line D-D of FIG. 14.

FIG. 16 is a cross section illustrating a state in which laser beam cutting is performed such that the polarizer of the OEL cell separated from the mother substrate of FIG. 15 is cut into two pieces.

FIG. 17 is a cross section illustrating a state in which laser abrasion is performed on a terminal resin.

FIG. 18 is a cross section illustrating the removal of the polarizer from a terminal section.

FIG. 19 is a cross section illustrating the removal of a residue of the terminal resin by plasma ashing.

FIG. 20 is a cross section illustrating the complete removal of the residue of the terminal resin by the plasma ashing.

FIG. 21 is a cross section according to the invention in which the polarizer is cut into two pieces by a laser beam at the boundary between the display area and the terminal section.

FIG. 22 is a cross section illustrating a state in which laser abrasion is performed between the terminal resin and the polarizer.

FIG. 23 is a cross section illustrating the removal of the polarizer from the terminal section.

FIG. 24 is a cross section illustrating the removal of a residue of the terminal resin from the terminal section by the plasma ashing.

FIG. 25 is a cross section in the vicinity of the terminal section of a completed OEL cell.

FIG. 26 is a cross section illustrating a method of depositing the terminal resin according to an alternative embodiment of the invention.

FIG. 27 is a cross section in the vicinity of the terminal section of an OEL cell completed according to the alternative embodiment of the invention.

### DETAILED DESCRIPTION OF THE PREFERRED EMBODIMENTS

Embodiments of the present invention will now be described in detail. Although the following explanation is based on the assumption that the invention is applied to an OELD device, the invention can also be applied to an LCD device.

### Embodiment 11

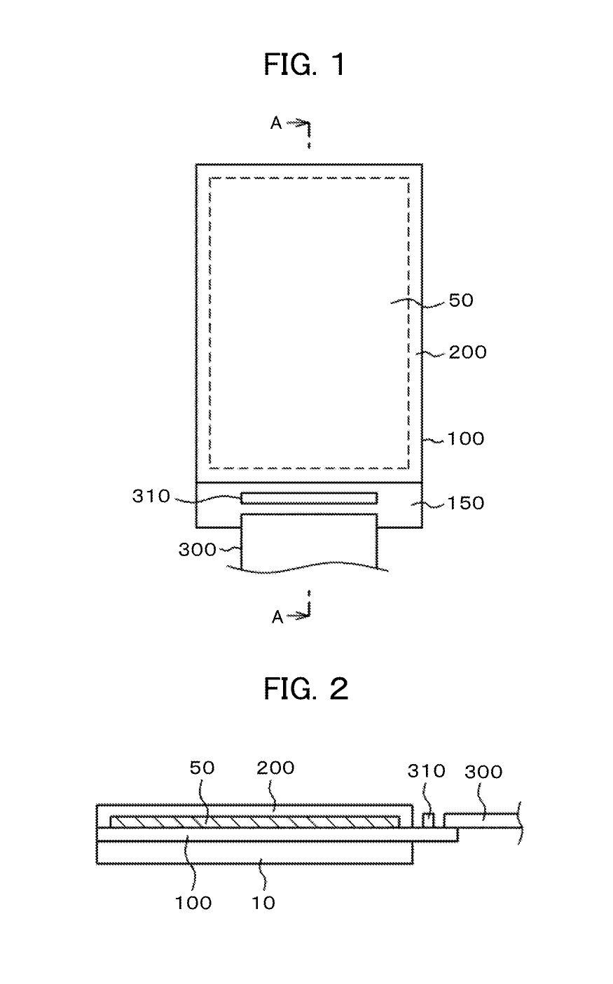

FIG. 1 is a plan view of an OELD having a flexible substrate 100 to which the invention is applied. FIG. 2 is a cross section taken along line A-A of FIG. 1. As illustrated in FIGS. 1 and 2, an array layer 50 including thin film transistors (TFTs) and an organic electroluminescent layer is formed on the flexible substrate 100. The flexible substrate 100 is covered by a polarizer 200. The array layer 50 is included in the display area.

In FIGS. 1 and 2, the section of the flexible substrate 100 that is not covered by the polarizer 200 serves as a terminal section 150. The wiring from the array layer 50 is connected to a driver IC 310 installed on the terminal section 150. The wiring is also connected from the driver IC 310 to a flexible wiring substrate 300 at the end of the terminal section 150. The flexible wiring substrate 300 supplies electric power and signals to the OELD device.

The flexible substrate 100 is formed of resin, for example, a polyimide, such that its thickness is in the range of 10 to 20 μm. The flexible substrate 100 can thus be bent flexibly. However, such a flexible substrate is mechanically fragile and unstable in terms of the shape of the display device. For this reason, a support substrate 10 is provided beneath the flexible substrate 100. The support substrate 10 can be formed of glass or resin.

The thickness of the support substrate 10 is in the range of about 0.1 to 0.5 mm. In the invention, because the flexible substrate 100 and the array layer 50 are formed on the support substrate 10 in the beginning, the support substrate 10 needs to have a thickness that allows the support substrate 10 to put through the production line for forming the array layer 50. It should also be noted that because it is inefficient to produce OELD devices one by one, the typical practice is to form multiple OELD devices on a single mother substrate so that they can later be separated into individual organic electroluminescent cells. Therefore, at an early stage of production, the support substrate of the invention is a large-sized mother substrate.

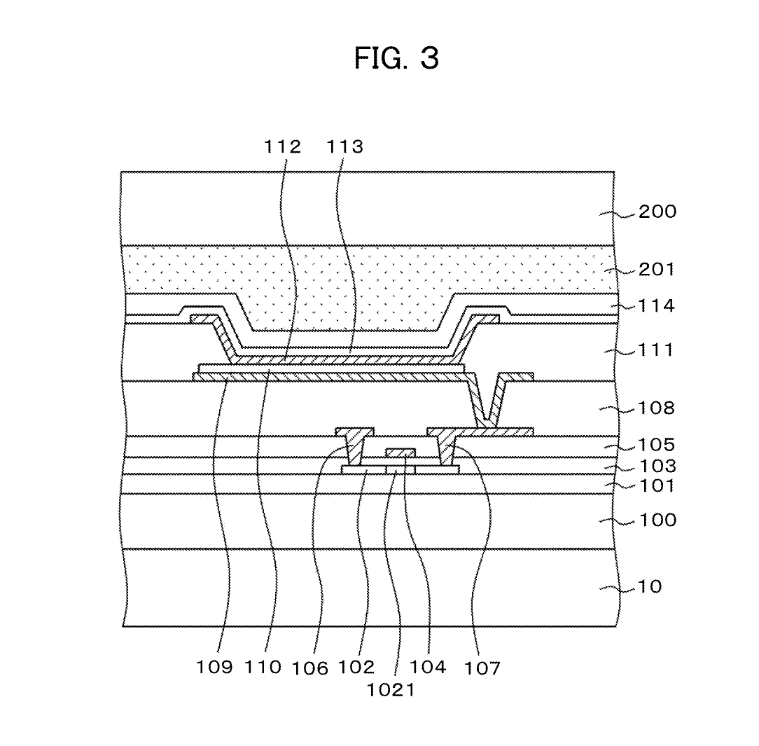

FIG. 3 is a cross section taken from the display area of FIG. 2 and illustrates an OELD device of the top-emission type. In FIG. 3, the 10 μm to 20 μm thick flexible substrate 100 is formed of a polyimide. The flexible substrate 100 can instead be formed of other resin or glass. If resin is to be used to form the flexible substrate 100, a slit coater can be used to apply, for example, a polyimide onto the support substrate 10. The support substrate 10 can then be baked to from the flexible substrate 100. The support substrate 10 can be glass or a resin film.

A substrate-side barrier layer 101 is formed on the flexible substrate 100. A primary purpose of the barrier layer 101 is to interrupt the flow of moisture from the polyimide side. The substrate-side barrier layer 101 is a laminate of SiO and SiN. The substrate-side barrier layer 101 can be made up of three layers: for example, from the substrate side, 50 nm thick SiO, 50 nm thick SiN, and 300 nm thick SiO. SiO and SiN can instead be SiOx and SiNx, respectively. Formed on the substrate-side barrier layer 101 is a semiconductor layer 102. This semiconductor layer 102 is formed by depositing a-Si by chemical vapor deposition (CVD) and then converting it into Poly-Si with the use of an excimer laser.

A gate insulating film 103 is formed to cover the semiconductor layer 102. The gate insulating film 103 is formed of SiO by CVD in which tetraethoxysilane (TEOS) is used. A gate electrode 104 is formed on the gate insulating film 103. Ion implantation is then used to convert the section of the semiconductor layer 102 that does not overlap the gate electrode 104 into a conductive layer. The other section of the semiconductor layer 102 that overlaps the gate electrode 104 serves as a channel section 1021.

An inter-layer insulating film 105 is formed to cover the gate electrode 104. The inter-layer insulating film 105 is formed of SiN by CVD. Through holes are then created in the inter-layer insulating film 105 and the gate insulating film 103. Provided in the through holes are a drain electrode 106 and a source electrode 107 for connection therebetween. As illustrated in FIG. 3, an organic passivation film 108 is then formed to cover the drain electrode 106, the source electrode 107, and the inter-layer insulating film 105. The organic passivation film 108 is formed thick (e.g., 2 to 3 μm) because it needs to act also as a planarizing film. The organic passivation film 108 is formed of, for example, acrylic resin.

A reflective electrode 109 is formed on the organic passivation film 108, and a lower electrode 110 is formed on the reflective electrode 109. The lower electrode 110, which serves as an anode, is formed of a transparent conductive film such as ITO. The reflective electrode 109 is formed of an Al alloy with a high reflectance. The reflective electrode 109 is connected to the source electrode 107 of the TFT via a through-hole formed in the organic passivation film 108.

An acrylic-made bank 111 is formed around the lower electrode 110. The purpose of the bank 111 is to prevent conductivity failure of next-formed layers (an OEL layer 112 including a light emitting layer and an upper electrode 113) resulting from stepped surfaces. The bank 111 is formed by applying a transparent resin, such as an acrylic resin, onto the entire surface and then creating a hole in the section of the resin that overlaps the lower electrode 110 so that light can be extracted from the OEL layer.

As illustrated in FIG. 3, the OEL layer 112 is formed on the lower electrode 110. The OEL layer 112 includes, for example, an electron injection layer, an electron transport layer, a light emitting layer, a hole transport layer, and a hole injection layer. Formed over the OEL layer 112 is the upper electrode layer 113, which acts as a cathode. The upper electrode 113 can be formed of a transparent conductive film such as indium zinc oxide (IZO) and indium tin oxide (ITO) or of a metal film such as a silver film.

To interrupt the flow of moisture from the side of the upper electrode 113, a surface barrier layer 114 is formed on the upper electrode 113. The surface barrier layer 114 is formed of SiN by CVD. Because the OEL layer 112 is easily affected by heat, the surface barrier layer 114 is formed by use of a lower temperature CVD, for example, 100 degrees Celsius.

Since the top-emission type OELD device includes the reflective electrode 110, its screen reflects external light, which in turn reduces the contrast of the screen. To prevent this, the polarizer 200 is disposed on the front surface side. This polarizer 200 is designed to prevent the reflection of external light. The polarizer 200 has an adhesive layer 201 on its one side. Thus, the polarizer 200 can be glued to the OELD device by pressing the polarizer 200 onto the surface barrier layer 114. The adhesive layer 201 is about 30 μm thick while the polarizer 200 is about 100 μm thick. As illustrated in FIGS. 1 and 2, the polarizer 200 and the adhesive layer 201 cover the peripheral area outside the array layer 50 as well.

In FIG. 3, since the flexible substrate 100 is formed of a 10 μm to 20 μm thick polyimide, it is mechanically fragile and unstable in terms of the shape of the flexible display device. Thus, the support substrate 10 is provided to stabilize the shape of the flexible display device. Various materials, thicknesses, and shapes can be selected for the support substrate 10 depending on the use of the flexible display device. However, the invention requires the thickness or material that allows the mother support substrate to be put through the processes for forming the flexible substrate and the array layer.

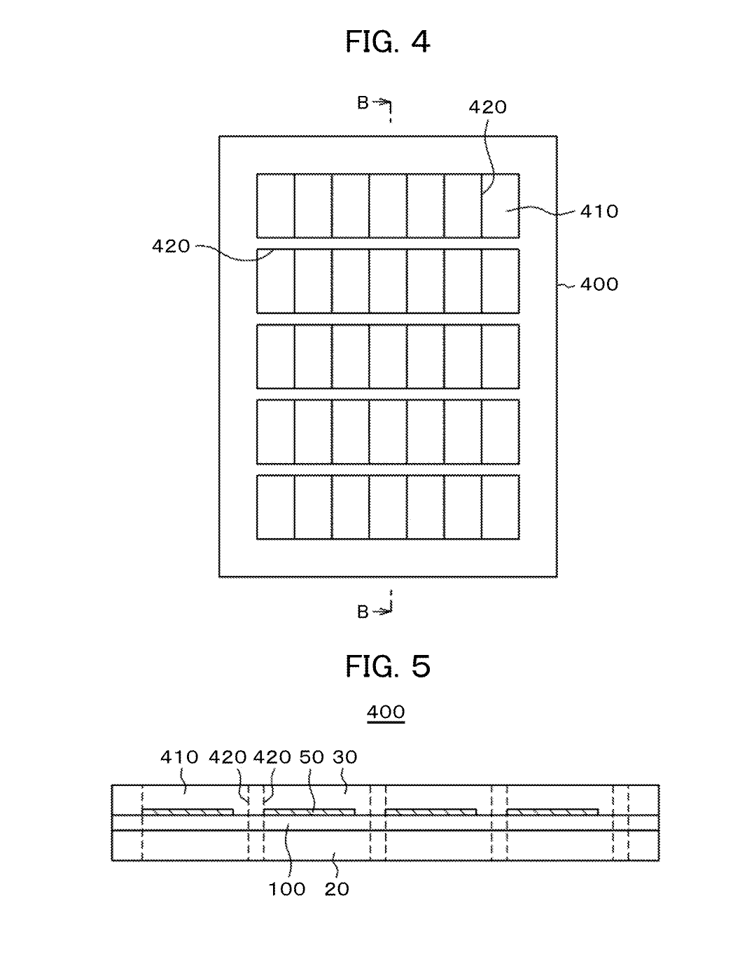

Since producing OELD devices one by one is inefficient, many OEL cells are formed on the mother substrate. After the completion of the mother substrate, the OEL cells are separated into individual cells. FIG. 4 is a plan view of a mother substrate 400. As illustrated in FIG. 4, thirty five (7×5) OEL cells 410 are arranged on the mother substrate 400. After the completion of the mother substrate 400, the OEL cells 410 are separated along the separation lines 420 into individual cells, each of which becomes an OELD device.

FIG. 5 is a cross section taken along line B-B of FIG. 4 when the invention is not applied. For simplification purposes, FIG. 5 illustrates the case where only four OEL cells 410 are provided. As in FIG. 1, a flexible resin (polyimide) substrate 100 is formed on a first carrier substrate 20, and an array layer 50 is formed on the flexible substrate 100 for each OEL cell. The first carrier substrate 20 needs to be one that can be put through the processes for forming the flexible substrate 100 and the array layer 50. A second carrier substrate 30 is formed to cover the array layer 50. The second carrier substrate 30 is used to protect the array layer 50 and the like during the processes and often formed of a resin film.

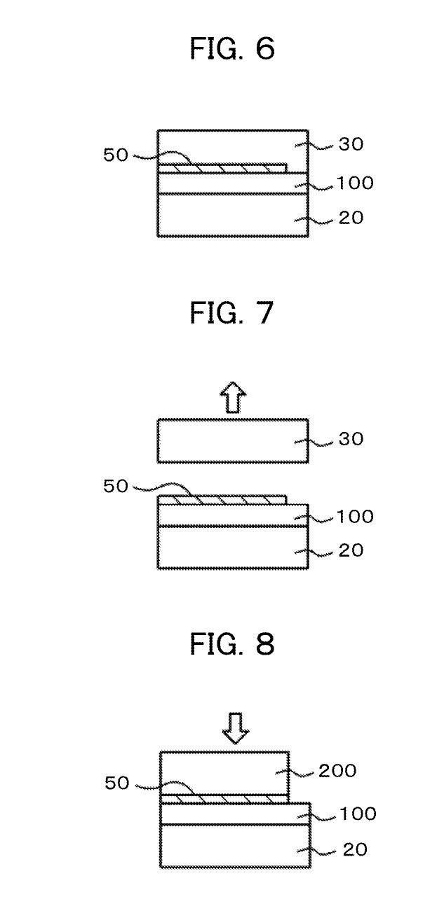

After the completion of the mother substrate 400 of FIG. 5, the OEL cells 410 are separated from the mother substrate 400 along the separation lines 420 of FIG. 5. FIG. 6 is a cross section of an OEL cell 410 separated from the mother substrate 400 of FIG. 5 along the separation lines 420. As illustrated in FIG. 6, the flexible substrate 100 is formed on the first carrier substrate 20, and the array layer 50 is formed on the flexible substrate 100. Also, the second carrier substrate 30 is glued such that it covers the flexible substrate 100 and the array layer 50.

As illustrated in FIG. 7, the second carrier substrate 30 is then removed. The second carrier substrate 30 is glued to the array layer 50 and the like by a low-viscosity adhesive so that it can be easily removed. Thus, the second carrier layer 30 can be removed without damaging the array layer 50.

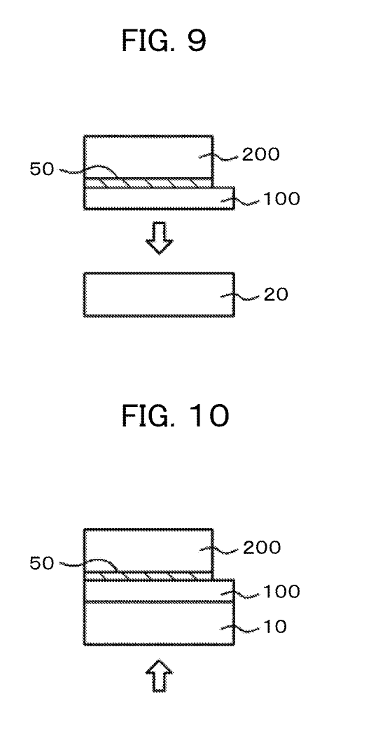

After the removal of the second carrier substrate 30, the polarizer 200 is glued to the array layer 50 as illustrated in FIG. 8. Since the polarizer 200 is part of the finished product, it is glued by a high-viscosity adhesive so that it will not come off. Thereafter, the first carrier substrate 20 is removed as illustrated in FIG. 9. The removal of the first carrier substrate 20 from the flexible substrate 100 formed of a polyimide or the like can be done by, for example, laser abrasion in which the boundary between the first carrier substrate 20 and the flexible substrate 100 is irradiated with a focused laser beam.

The support substrate 10 is then glued to the bottom surface of the flexible substrate 100 as illustrated in FIG. 10. Since the support substrate 10 is part of the finished product, a high-viscosity adhesive is used to glue the support substrate 10 to the flexible substrate 100.

In the above method, the first carrier substrate 20 and the second carrier substrate 30 that are used only for the manufacturing processes are not used thereafter and thus discarded. In addition, the above method requires the step of gluing the support substrate 10 after removing the first carrier substrate 20 as well as the step of gluing the polarizer 200 after removing the second carrier substrate 30, which increases manufacturing cost.

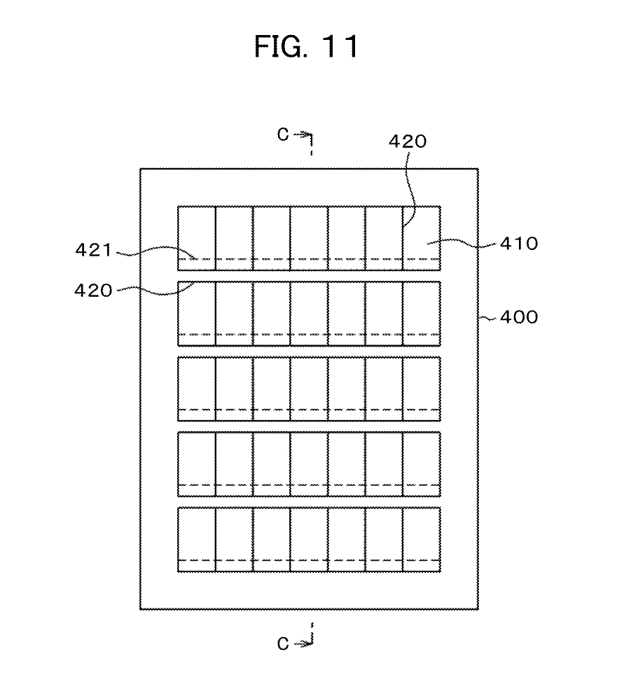

To skip such steps, an alternative method would be to glue the support substrate 10 in place of the first carrier substrate 20 and the polarizer 200 in place of the second carrier substrate 30. This method, however, has the following drawbacks, as will be described with reference to FIGS. 11 to 13.

FIG. 11 is a plan view of a mother substrate 400 according to the above alternative method. FIG. 11 is the same as FIG. 4 in terms of the arrangement of OEL cells 410. However, FIG. 11 differs from FIG. 4 in that, in the former, the flexible substrate 100 is sandwiched by a large-sized mother support substrate and a large-sized mother polarizer in place of the first carrier substrate and the second carrier substrate, respectively. FIG. 11 is also the same as FIG. 4 in that, after the completion of the mother substrate, the OEL cells 410 are separated from the mother substrate along the separation lines 420. However, in FIG. 11, the polarizer needs to be removed from the terminal sections; thus, half-cutting lines 421 are drawn by the dotted lines.

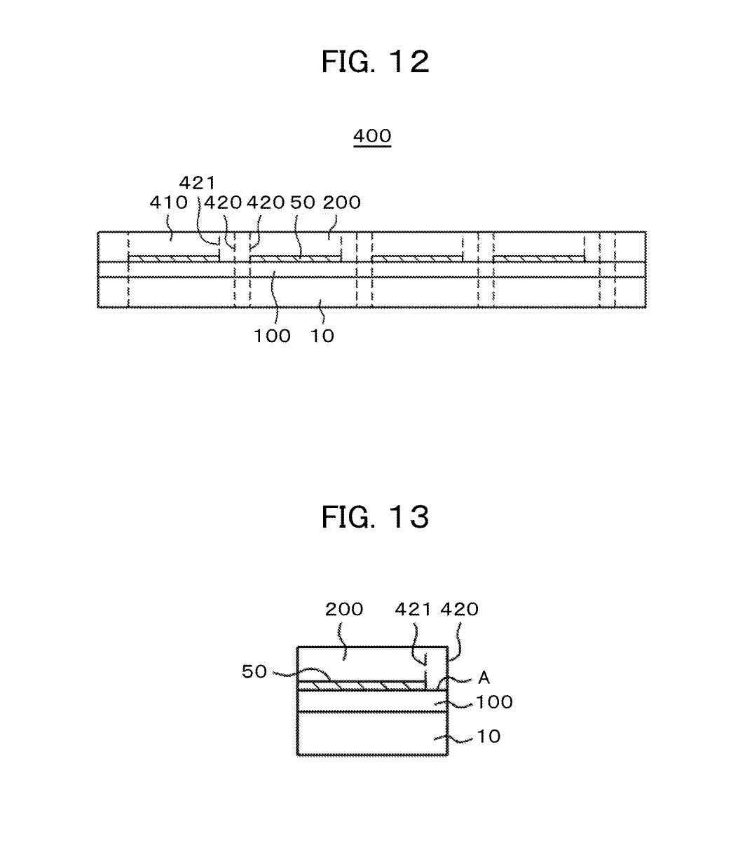

FIG. 12 is a cross section taken along line C-C of FIG. 11. FIG. 12 is the same as FIG. 5 in terms of the arrangement of the OEL cells 410. However, FIG. 12 differs from FIG. 5 in that, in the former, the support substrate 10 is located beneath the flexible substrate 100 and the polarizer 200 is located above the array layer 50. Also, FIG. 12 includes the half-cutting lines 421 that are used to remove the polarizer 200 from the terminal sections, in addition to the separation lines 420 that are used to separate the OEL cells. Cuts are made along the half-cutting lines 421 before or after the removal of the OEL cells from the mother substrate.

FIG. 13 is a cross section of an OEL cell separated from the mother substrate. As illustrated in FIG. 13, the support substrate 10 is located beneath the flexible substrate 100, and the polarizer 200 is glued over the array layer 50. The support substrate 10 is glued to the flexible substrate 100 with strong adhesive force, and the polarizer 200 is glued to the array layer 50 and the terminal section with strong adhesive force. As stated above, the half-cutting line 421 is used to remove the polarizer from the terminal section.

However, since the polarizer 200 is glued to the terminal section with strong adhesive force, making a cut on the polarizer along the half-cutting line 421 does not help to remove the polarizer 200 from the terminal section. In other words, since the adhesive force of the polarizer 200 is strong in the area A of FIG. 13, the polarizer 200 cannot be removed therefrom even if a half cut is made along the half-cutting line 421.

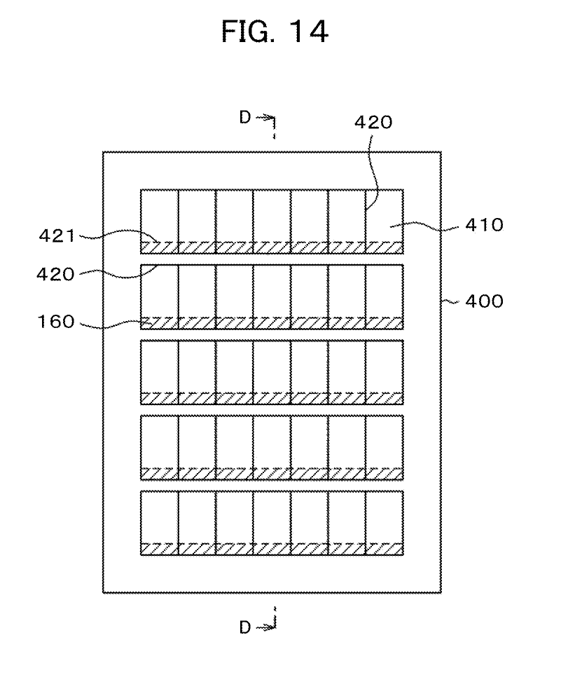

The invention is designed to solve the above problem. FIG. 14 is a mother substrate 400 according to the invention. FIG. 14 is the same as FIGS. 4 and 11 in terms of the arrangement of the OEL cells 410. In FIG. 14, however, a terminal resin is deposited at the interface between the terminal section of each OEL cell 410 and the polarizer 200.

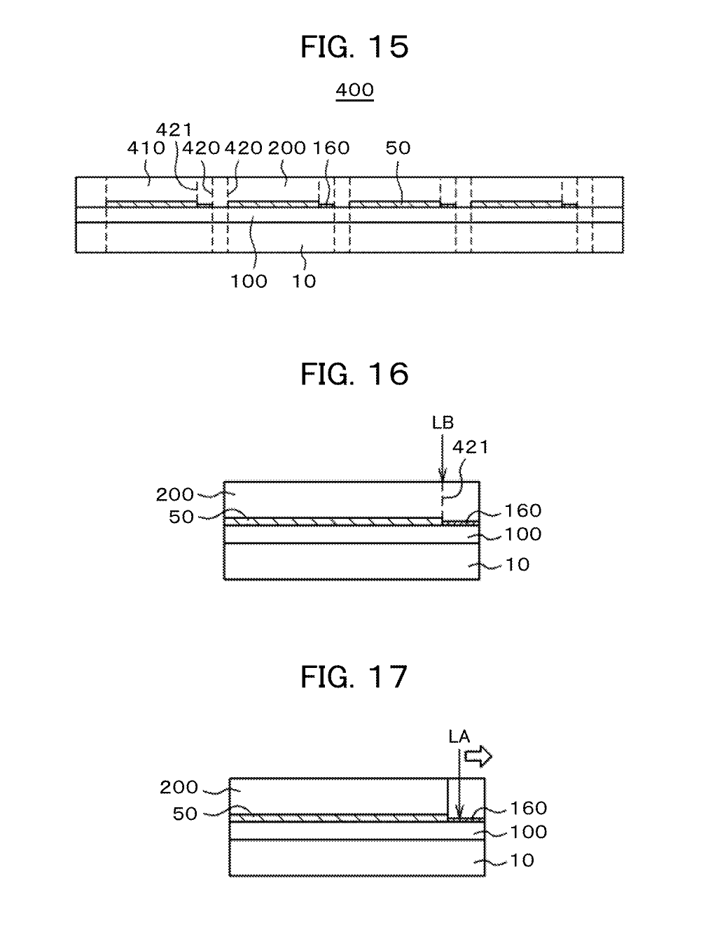

FIG. 15 is a cross section taken along line D-D of FIG. 14. FIG. 15 is the same as FIG. 12 in terms of the arrangement of the OEL cells 410. In FIG. 15, the support substrate 10 is located beneath the flexible substrate 100, and the polarizer 200 is located above the array layers 50. Further, a terminal inter-layer 160 is formed at each interface between the terminal section of an OEL cell 410 and the polarizer 200. The OEL cells 410 are separated from the mother substrate along the separation lines 420, and the half-cutting lines 421 are formed at the boundaries between the terminal sections and the array layers.

The OEL cells 410 can be removed from the mother substrate either by a laser beam or a machine blade. Also, in removing the polarizer 200 from the terminal sections, a laser beam or a machine blade can be used to make half cuts along the half cutting lines 421. The making of half cuts along the half cutting lines 421 can be done before or after the OEL cells are separated from the mother substrate.

FIG. 16 illustrates an example in which a half cut 421 is made by a laser beam LB after one OEL cell is separated. If the polarizer 200 is formed of polyethylene terephthalate (PET), it is preferred that the laser beam LB be a CO₂ laser beam having a spectrum of 9000 to 10000 nm.

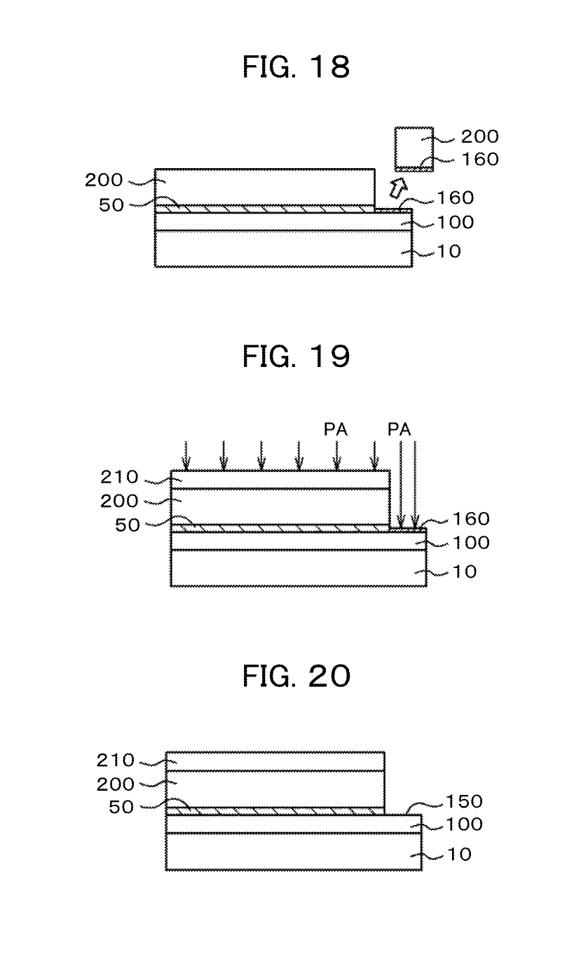

However, simply making a half cut 421 as in FIG. 16 does not help to remove the polarizer 200 from the terminal section since the adhesive force of the polarizer 200 is strong. Distinctive features of the invention are that the terminal inter-layer 160 is formed on the terminal section and that, as illustrated in FIG. 17, the interface between the terminal inter-layer 160 and the polarizer 200 is irradiated with a focused laser beam LA and the beam is scanned across the terminal section. By doing so, the laser beam LA causes the terminal inter-layer 160 to evaporate; in other words, the polarizer 200 can be removed from the terminal section by laser abrasion, as illustrated in FIG. 18.

It is preferred that the terminal inter-layer 160 be formed of a material that absorbs the wavelength of light passing through the resin of the polarizer 200. If the polarizer 200 is formed of polyethylene terephthalate (PET), the terminal inter-layer 160 can be formed of, for example, a polyimide. PET relatively allows the passage of light with a wavelength of, for example, 355 nm. An example of a polyimide that absorbs light with a wavelength of 355 nm is PMDA-ODA.

The terminal inter-layer 160 can be deposited on the terminal section by flexography printing, ink jet printing, or the like. The thickness of the terminal inter-layer 160 is in the range of 100 nm to 10 μm and preferably in the range of about 500 nm to 2 μm. To perform laser abrasion on the terminal inter-layer 160 that absorbs light with a wavelength of 355 nm, a YAG laser can be used via its third harmonic (wavelength of 355 nm).

After laser abrasion is performed to remove the polarizer 200 from the terminal section as in FIG. 18, there remains a residue of the terminal inter-layer 160 on the terminal section. Unless this residue is removed, wiring connections cannot be established from the terminal section to the driver IC, the flexible wiring substrate, and so on. As illustrated in FIG. 19, after the OELD device is completed, a surface protection film 210 having a slightly adhesive material is glued to the surface of the polarizer 200 so that the surface will not be damaged. The surface protection film 210 is formed primarily of PET or PP (polypropylene), and an acrylic resin is attached as the slightly adhesive material. The thickness of the surface protection film 210 is in the range of 25 to 50 μm.

Thus, as shown in FIG. 19, to remove the above polyimide residue, dry etching or plasma ashing PA can be performed with the protection film 210 having a slightly adhesive material used as a mask. The reference symbol PA of FIG. 19 denotes such plasma ashing performed on a surface of the OELD device. To perform the plasma ashing PA, an oxygen plasma asher can be used.

By performing the plasma ashing PA, the terminal section of the OELD device can be cleaned as illustrated in FIG. 20, and wiring connections can be established from the terminal section to the driver IC and to the flexible wiring substrate. It should be noted that since the surface protection film 210 is much thicker than the polyimide residue, the plasma ashing PA does not alter the external appearance of the surface protection film 210.

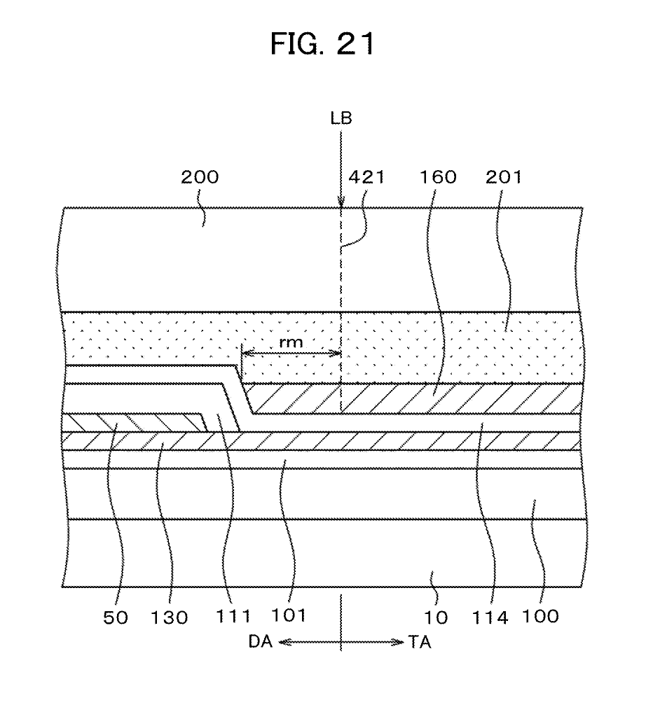

FIGS. 21 through 25 are detailed cross sections illustrating the above process of removing the polarizer from the terminal section. In FIG. 21, a polyimide having a thickness of 10 to 20 μm (flexible substrate 100) is formed on the support substrate 10. In the invention, the support substrate 10 is not removed and thus used as a component of the finished product. Formed on the flexible substrate 100 is the substrate-side barrier layer 101, which has been described with reference to FIG. 3. Also, a wiring layer 130 is formed on the substrate-side barrier layer 101. This wiring layer 130 refers to all the wires formed in the same layer as those of the gate electrode and drain electrode of FIG. 3; it extends from a display area DA up to a terminal section TA.

The array layer 50 is formed in the display area DA and includes the OEL layer of FIG. 3. An organic film 111 is formed to cover the array layer 50. The organic film 111 is the same as that of the bank of FIG. 3. The surface barrier layer 114 is formed to cover the organic film 111 and the array layer 50. The surface barrier layer 114 is present not only in the display area DA but also in the terminal section TA, thereby protecting the wiring layer 130.

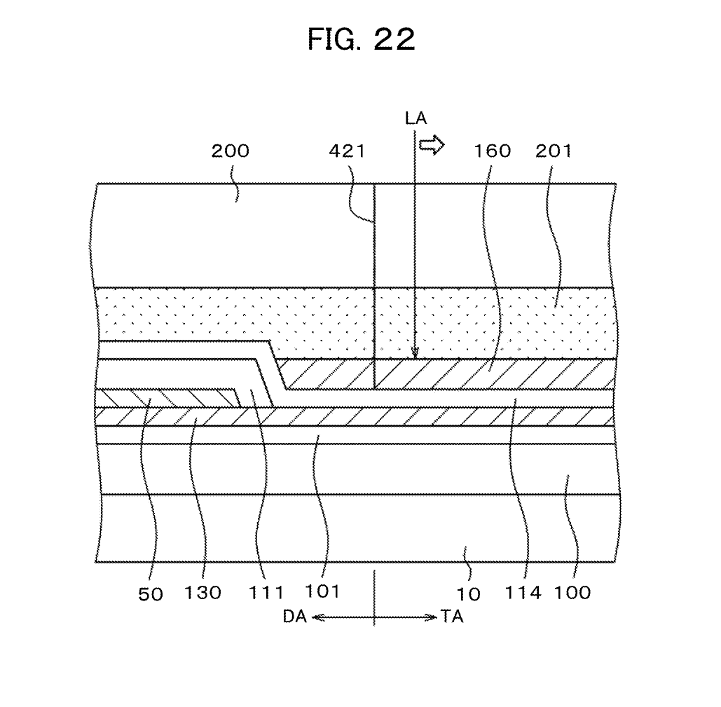

Another feature of the invention is that the terminal inter-layer 160 that covers the surface barrier layer 114 at the terminal section is formed of, for example, a polyimide. The polarizer 200 is glued via the adhesive layer 201 such that it covers the surface barrier layer 114 and the terminal inter-layer 160. In FIG. 22, the laser beam LB is radiated along the half-cutting line 421 to cut the polarizer 200 and the terminal inter-layer 160. In FIG. 21, the half-cutting line 421 separates the OELD into the display area DA (left side of the line 421) and the terminal section TA (right side of the line 421).

In terms of the object of the invention, the terminal inter-layer 160 has only to be formed in the terminal section TA. However, because it is impossible to precisely match the position of the half cut made by the laser beam with the edge of the terminal inter-layer 160, the terminal inter-layer 160 is extended from the half-cutting line 421 toward the side of the display area DA by a distance rm, which is in the range of, for example, 50 to 100 μm. This prevents the upper barrier layer 114 and the wiring layer 130 from being damaged due to laser beam displacement during the making of the half cut 421 by the laser beam LB or during laser abrasion.

FIG. 22 is a cross section illustrating laser abrasion in which the laser beam LA is scanned across the terminal inter-layer 160 in the terminal section TA after the half cut is made by the laser beam. In FIG. 22, the half cut line 421 is represented by a solid line, and the polarizer 200 has already been cut.

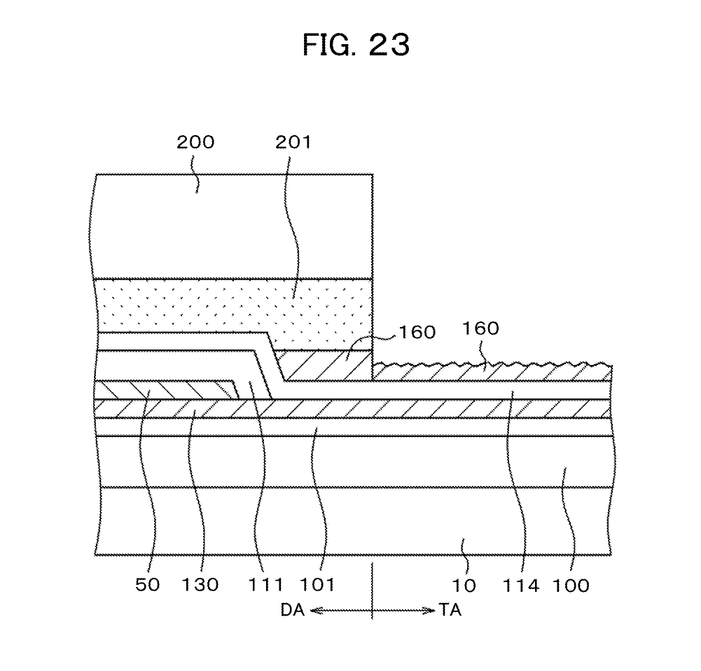

FIG. 23 is a cross section illustrating the removal of the polarizer 200 from the terminal section TA by the laser abrasion. As illustrated, the terminal inter-layer 160 has not completely been removed by the laser abrasion, and part of the terminal inter-layer 160 remains in the terminal section TA, forming surface irregularities.

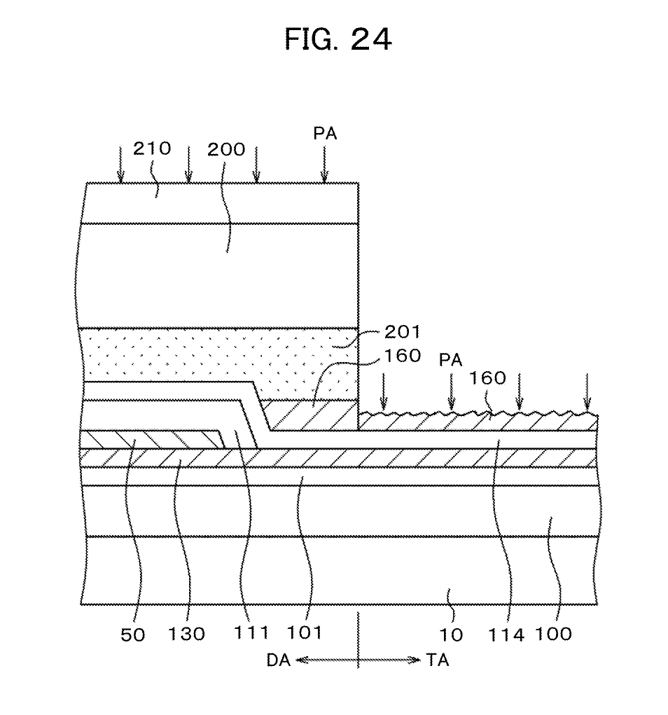

The protection film 210 having a slightly adhesive material is then glued to the polarizer 200 located in the display area of the OEL cell of FIG. 23. Thereafter, as illustrated in FIG. 24, the plasma ashing PA is performed on surfaces of the OEL cell to remove the residue of the terminal inter-layer 160.

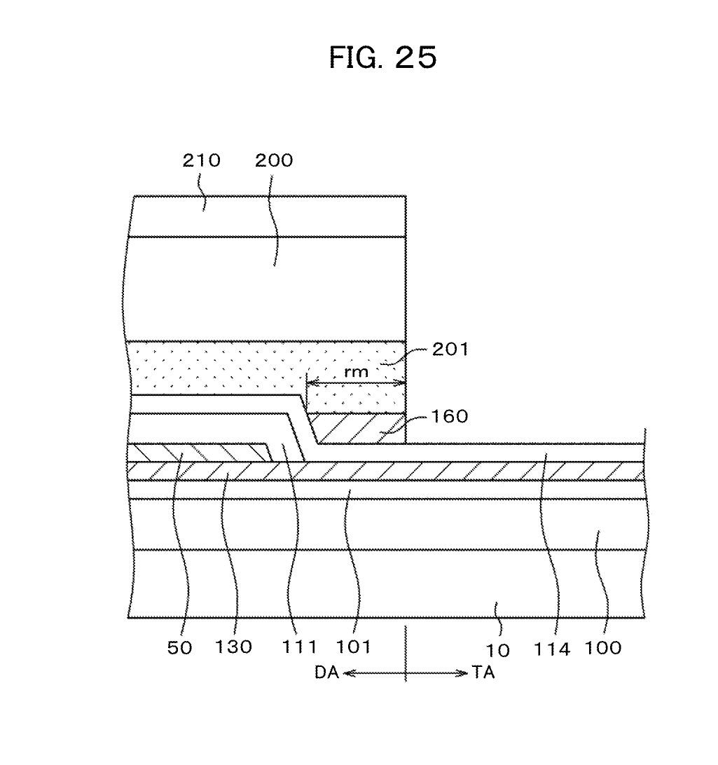

FIG. 25 is a cross section illustrating the vicinity of the terminal section of the thus-formed OEL cell. As illustrated in FIG. 25, the part of the terminal inter-layer 160 that is extended by the distance rm is left on the surface barrier layer 114 and below the polarizer 200. This prevents, during the laser abrasion, the surface barrier layer 114 from being damaged by the laser beam due to manufacturing tolerance.

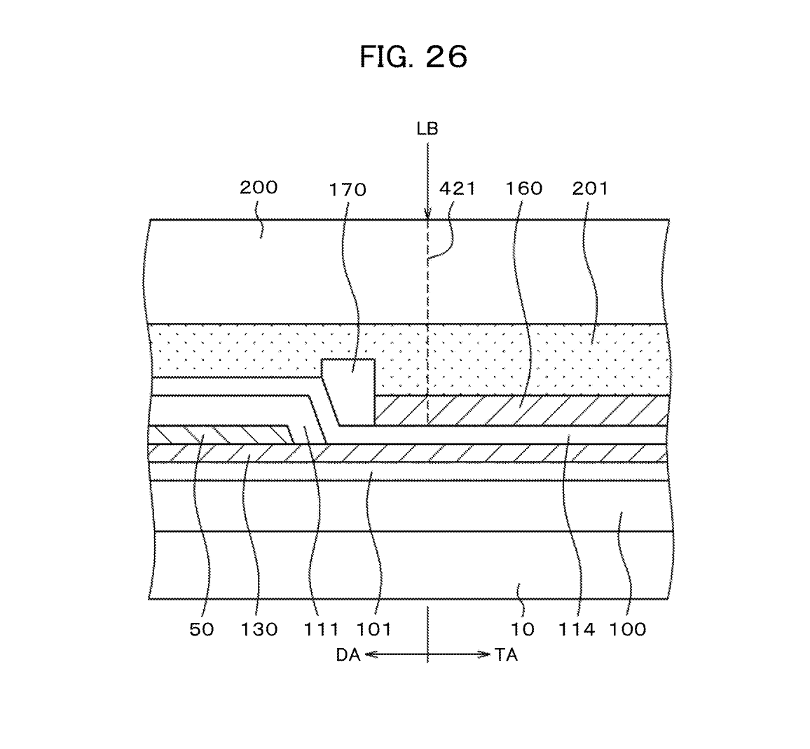

In a case where the terminal inter-layer 160 is formed thick, display quality may be lowered by the terminal inter-layer 160 flowing toward the array layer 50. FIG. 26 illustrates an example in which a bank-shaped rib 170 is formed so that the terminal inter-layer 160 is not flow toward the array layer 50. The rib 170 is created in the form of a bank in parallel with the boundary between the terminal section and the display area. The rib 170 can be formed of, for example, an acrylic resin.

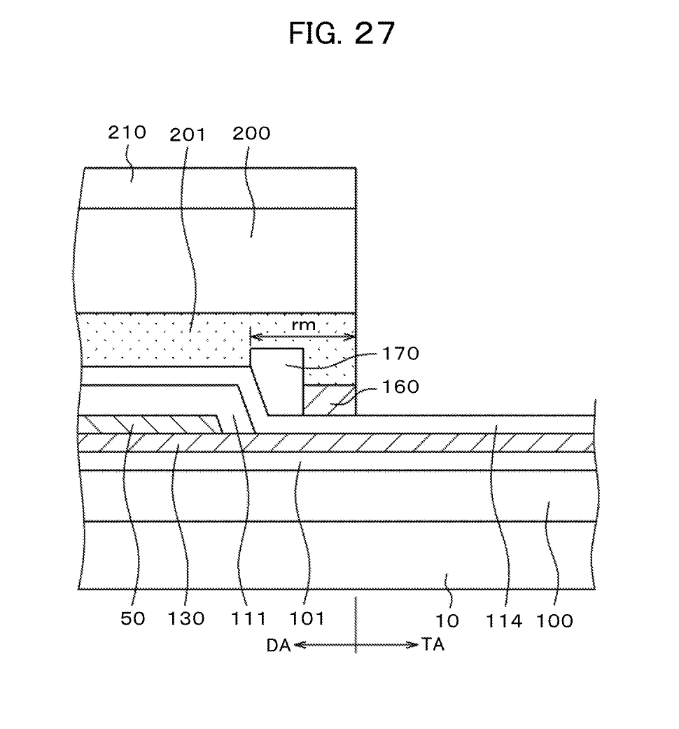

FIG. 26 is the same as FIGS. 21 to 24 in terms of the other steps that follow, including depositing a terminal resin, making a half cut by a laser beam, removing the polarizer by laser abrasion, and removing a residue of the terminal resin. FIG. 27 is a cross section illustrating the vicinity of the terminal section of an OEL cell according to the above alternative embodiment. As illustrated in FIG. 27, the terminal inter-layer 160 and the rib 170, which collectively occupy the distance rm, are left on the surface barrier layer 114 and below the polarizer 200. This prevents, during the laser abrasion, the surface barrier layer 114 from being damaged by laser beam displacement.

As stated above, the invention uses the mother substrate as the support substrate 10 (i.e., as part of the finished product). Depending on cases, the support substrate may need to be a 0.5 mm thick glass plate so that the mother substrate can be put through production lines, while it may need to be equal to or less than 0.2 mm in thickness as the support substrate 10 (as part of the finished product). In the latter case, after the completion of the mother substrate, it can be abraded to obtain a support substrate of the required thickness.

In addition, although we have described the case where the polarizer is disposed so as to cover the display area, it is also possible to use an optical sheet of low transmittance in place of the polarizer to prevent light reflection. External light passes through the optical sheet twice while the light from the light emitting elements passes through it only once. Thus, by reducing the transmittance of the optical sheet, contrast can be prevented from decreasing due to external light. The invention can also be applied to such a structure. In such a case as well, it is preferred that the wavelength range in which light is absorbed be different for the optical sheet and for the terminal resin.

Further, although we have stated that, according to the invention, the support substrate is included in the finished product, there are also cases where it is not necessarily required for the flexible display device. In such cases, the support substrate can be removed from the flexible resin-made substrate by laser abrasion or the like during the final stage of manufacturing.

We have described how the invention is applied to an OELD device. However, since LCD devices can also be made thin and flexible, the invention can be applied to such flexible LCD devices as well.

What is claimed is:

1. A display device comprising:
a bendable substrate having thereon a display area and a terminal section;
an array layer formed in the displayer area; and
an inter-layer of a predetermined width formed between the array layer and the terminal section,
wherein the inter-layer does not overlap the array layer and the terminal section.

2. The display device of claim 1, wherein an optical sheet is glued in the display area and overlaps the inter-layer.

3. The display device of claim 1, wherein the optical sheet and the inter-layer are formed of different materials.

4. The display device of claim 1, wherein the wavelength range in which light is absorbed is different for the optical sheet and for the inter-layer.

5. The display device of claim 1, wherein the inter-layer is a polyimide.

6. The display device of claim 1, wherein the optical sheet is formed of PET.

7. The display device of claim 1, wherein the optical sheet is a polarizer.

8. The display device of claim 1, wherein the bendable substrate is formed of a resin sheet.

9. The display device of claim 1, wherein the resin sheet is formed of a polyimide.

10. The display device of claim 1, wherein the inter-layer is formed on an inorganic surface barrier layer formed in the display area.

11. The display device of claim 1, wherein a bank-shaped rib is formed between the inter-layer and the array layer and is in contact with the inter-layer.

12. The display device of claim 1, wherein an optical sheet is glued in the display area and the optical sheet overlaps the inter-layer and the bank-shaped rib.

13. The display device of claim 1, wherein a support substrate is formed on a rear surface of the bendable substrate.

14. The display device of claim 13, wherein the support substrate is glass.

15. The display device of claim 1, wherein the display device is an organic electroluminescent display.

16. The display device of claim 1, wherein the display device is a liquid crystal display.

17. A method of manufacturing a flexible display device, comprising:
forming a flexible substrate on a support substrate;
forming a display area and a terminal section on the flexible substrate;
forming an array layer in the display area;
forming an inter-layer in the terminal section;
gluing an optical sheet so that the optical sheet covers the array layer and the inter-layer;
cutting the optical sheet at the boundary between the display area and the terminal section; and
performing laser abrasion on the inter-layer formed in the terminal section to remove a part of the optical sheet, the part covering the terminal section.

18. The method of claim 17, wherein a residue of the inter-layer, the residue remaining in the terminal section, is removed by plasma ashing or dry etching.

19. A method of manufacturing a flexible display device, comprising:
forming a flexible substrate on a support substrate;
forming a display area and a terminal section on the flexible substrate;
forming an array layer in the display area;
forming a bank-shaped rib between the array layer and the terminal section;
applying a resin to the terminal section by using the rib as an anti-overflow mechanism and baking the resin to form an inter-layer;
gluing an optical sheet so that the optical sheet covers the array layer and the inter-layer;
cutting the optical sheet at a boundary between the display area and the terminal section; and
performing laser abrasion on the inter-layer formed in the terminal section to remove a part of the optical sheet, the part covering the terminal section.

20. The method of claim 19, wherein a residue of the inter-layer, the residue remaining in the terminal section, is removed by plasma ashing or dry etching.
